(19) United States
(12) Patent Application Publication
(10) Pub. No.: US 2008/0137294 A1
(43) Pub. Date: Jun. 12, 2008

(54) Heat-dissipating fan fixing device

(75) Inventor: Chun-Ying Yang, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/636,435

(22) Filed: Dec. 11, 2006

(51) Int. Cl. H05K 7/20; G06F 1/20

(52) U.S. Cl. 361/695; 361/687

(57) ABSTRACT

A heat-dissipating fan fixing device, for accommodating and fixing a fan and mounted on a case is provided, which includes a frame, a plurality of hooks, and a stopping piece. The frame has a first end and a second end being opposite to each other. Between the first end and the second end, an accommodating space through the frame is formed for accommodating and fixing the fan. The hooks are formed on the first end and extend towards a protruding direction. The stopping piece is formed on a side edge of the first end. Thus, when the frame is joined with the case and moves along the protruding direction of the hooks, each hook catches the case, and then, the stopping piece is embedded into the case, so as to stop the frame form sliding along the opposite direction, thereby fixing the frame on the case.

### BACKGROUND OF THE INVENTION

1. Field of Invention

The present invention relates to a heat-dissipating fan fixing device, and more particularly, to a fixing base structure, capable of stacking and assembling a plurality of heat-dissipating fans thereon according to the heat dissipation requirements.

2. Related Art

A main board, a CPU chip, and various disk drivers are installed within a computer case, the above units and elements generate a great deal of heat. In order to prevent the heat from negatively affecting the operation of the computer, it is necessary to take measures to dissipate the heat, so generally the design of a heat-dissipating fan is further required.

In the conventional method for assembling a heat-dissipating fan to a computer case, a plurality of screws or other locking elements are used to fix the heat-dissipating fan on the computer case. It may meet the demands for the computer host in which only one to two heat-dissipating fans are required. However, as for the relatively large-scale computer case, for example, the case of a server, which requires a large mount of heat-dissipating fans, the assembling operation is performed on each heat-dissipating fan, so it will be time consuming for assembling heat-dissipating fans.

With reference to US Patent Publication No. U.S. Pat. No. 6,587,342 (hereinafter referred as patent 342), patent 342 provides an embedded heat-dissipating fan module, wherein the snapping manner is used to replace the fixing manner of using screws or locking elements, so as to achieve the object of quick assembling and disassembling. As shown in FIG. 2 of patent 342, a plate body 40 and a plate body 40′ respectively extend outwards from both sides of the body 31, which have two fan vents 42 respectively, and the number of the fan vents 42 are designed according to requirements. A first fan cover 32a and a second fan cover 32b are pivotally connected to the body 31 respectively, so that the first fan cover 32a and the second fan cover 32b form a space with the plate body 40 and the plate body 40′ respectively for accommodating the fan 11, and two fan vents are formed on each plate body 40, 40′, for accommodating and disposing two fans 11 respectively.

The heat-dissipating fans in patent 342 are assembled along the extending direction of the plate body, that is, a plurality of heat-dissipating fans may be individually assembled on the case. Although the number of the heat-dissipating fans may be increased or decreased according to the heat dissipation requirements, too much area of the case is occupied. Under the circumstance of a limited case area, when being applied in a computer case with relatively large heat dissipation requirements, there is no sufficient area for disposing the heat-dissipating fans. Also, the number of the vents on the case is constant, so it is impossible to increase the number of fans as needed. Therefore, recently, it has become a technical issue to be solved that how to fix the heat-dissipating fan without using screws or other locking components, wherein the number of the heat-dissipating fans can be randomly increased or decreased according to the heat dissipation effect of the computer host, without occupying an excessive case area.

### SUMMARY OF THE INVENTION

According to the above prior art, a user needs to use assembling tools to lock and fix the heat-dissipating fans on the case, which is time-consuming, and quite a lot of case area is occupied by heat-dissipating fans. Accordingly, an objective of the present invention is to provide a heat-dissipating fan fixing device, which enables the user to assemble the heat-dissipating fan on the case without using any assembling tools, and saving the case area by heat-dissipating fan fixing device.

In order to achieve the above objective, the present invention provides a heat-dissipating fan fixing base, which is used to accommodate and fix a fan and is mounted on a case. The heat-dissipating fan fixing base includes a frame, a plurality of hooks, and a stopping piece. The frame has a first end and a second end, and between the first end and the second end, an accommodating space through the frame is formed for accommodating and fixing the fan. The hooks are formed on the first end and extend towards a protruding direction, for catching the case. The stopping piece is formed on a side edge of the first end, so as to be embedded into the case and to stop the frame from sliding along the opposite direction of the protruding direction, thereby fixing the frame on the case.

The heat-dissipating fan fixing base of the present invention further includes a plurality of positioning pieces and a buckle base. The plurality of positioning pieces is disposed on the second end of the frame corresponding to each hook of another heat-dissipating fan fixing base, for bearing against each hook along the protruding direction, so as to make another frame be fixed with the first end of the frame via the second end. The buckle base is disposed on the second end of the frame, for the stopping piece of another heat-dissipating fan fixing device to embed therein, thus, another heat-dissipating fan fixing device is stopped from sliding along the opposite direction of the protruding direction, so as to stack the two heat-dissipating fan fixing devices together, thus, two fans are stacked and disposed on the case to enhance the ventilating effect.

According to the heat-dissipating fan fixing devicee disclosed by the present invention, the hooks of the heat-dissipating fan fixing device are used to assemble the heat-dissipating fan on the case, without using any tools and screws, so as to simplify the stacking and assembling process and reduce the operation time. Meanwhile, the positioning pieces and the buckle base at another end are used to stack the frame with another frame at the original case position, so as to be continuously stacked and assembled into a heat-dissipation structure with a plurality of heat-dissipating fans, thereby saving the occupied case area. In addition, the number of the required heat-dissipating fans may be increased or reduced according to the requirements of the heat-dissipation efficiency. For example, when it is intended to increase or reduce the heat-dissipation efficiency, the number of the stacked and assembled heat-dissipating fans may be increased or reduced accordingly, which has a large using variation flexibility.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1A is a front stereogram of a first embodiment of the present invention;

FIG. 1B is a back stereogram of the first embodiment of the present invention;

FIG. 2 is a schematic view of each hook and stopping piece snapping with the case of the first embodiment of the present invention;

FIG. 3 shows a stacking and assembling state of the first embodiment of the present invention;

FIG. 4 is a stereogram of the appearance of a wind scooper of a second embodiment of the present invention; and

FIG. 5 is a stereogram of the appearance of the second embodiment of the present invention disposed with the wind scooper.

### DETAILED DESCRIPTION OF THE INVENTION

In order to further understand the objective, construction, feature, and function of the present invention, it is described below in great detail through the embodiments.

The implementation method of the present invention will be illustrated below through the following specific embodiments. It is easy for those skilled in the art to understand other advantages and efficacy of the present invention through the content of the specification. The present invention also can be implemented and practiced through other different specific embodiments, and the details of the specification may be changed and modified depending upon different viewpoints and applications, without departing from the spirit and scope of the invention.

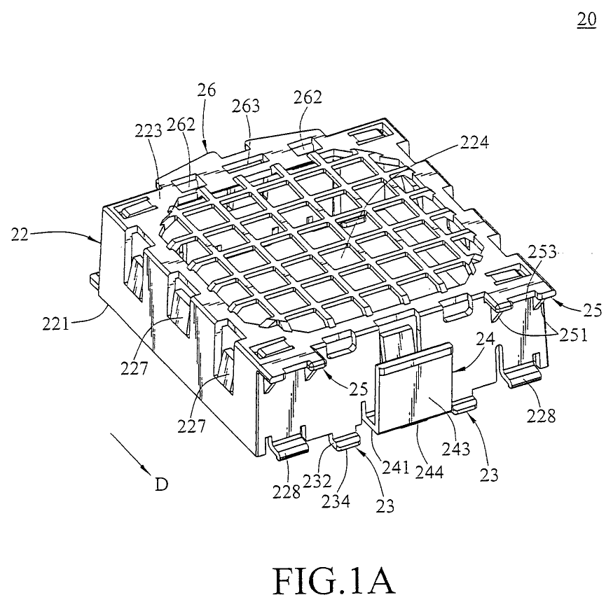

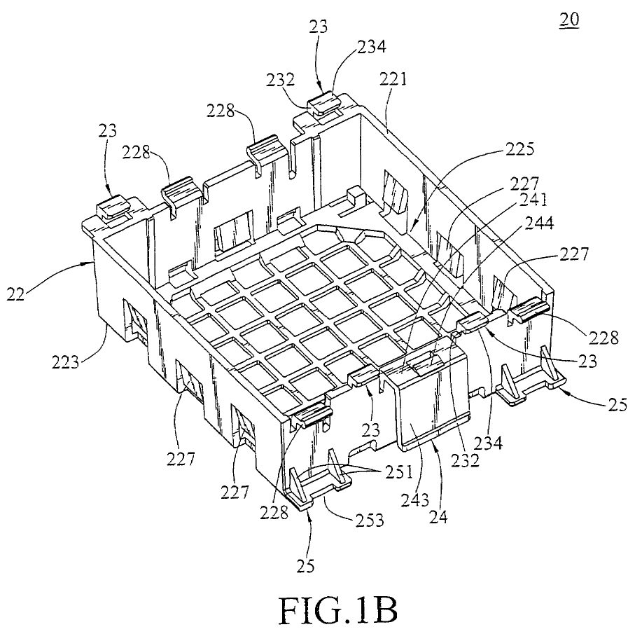

Referring to FIGS. 1A, 1B, 2, and 3, a heat-dissipating fan fixing device 20 is used to accommodate a heat-dissipating fan 40 therein, and it is mounted on a case 50. The heat-dissipating fan fixing device 20 includes a frame 22, a plurality of hooks 23, a stopping piece 24, a plurality of positioning pieces 25, and a buckle base 26.

The frame 22 has a first end 221 and a second end 223 being opposite to the first end 221, and openings 224 are formed on the first end 221 and the second end 223 respectively. Herein, the second end 223 is a hollow reticulation, for preventing foreign matters from entering. An accommodating space 225 through the frame 22 is formed between the first end 221 and the second end 223, which is used to accommodate and fix the heat-dissipating fan 40. The heat-dissipating fan 40 has fan blades 41 and a driving motor 42, wherein the driving motor 42 drives the fan blades 41 to rotate and thereby making the air to flow, so as to dissipate the heat. In addition, a plurality of isolating pieces 228 is disposed at the side edge of the first end 221 of the frame 22, herein, the number of the isolating pieces 228 is two, and it is not limited to this. Furthermore, a plurality of pads 227 is disposed on the wall between the first end 221 and the second end 223, which bears against the heat-dissipating fan 40 towards the direction of the accommodating space 225 of the frame 22.

The hooks 23 are formed on the first end 221 of the frame 22, and herein, the hooks 23 are located at two opposite side edges of the first end 221, but it is not limited to this. Furthermore, the hooks 23 are provided for the frame 22 to be joined with the case 50 or with another frame, so the number of the hooks 23 must reach the lowest number that is required for surely achieving the joining and fixing purposes, and herein, there are two hooks 23 at each side edge, and totally there are four hooks. Each hook 23 has a connecting portion 232 and a hooking portion 234, wherein the connecting portion 232 extends along one side edge of the first end 221, and the hooking portion 234 extends opposite to the connecting portion 232 and towards a protruding direction D.

The stopping piece 24 is formed on a side edge of the first end 221 of the frame 22, and located between the hooks 23 at the same side, wherein the stopping piece 24 has a joining portion 241, a pressing portion 243, and a bump 244. The joining portion 241 extends along a side edge of the first end 221 and joins with the pressing portion 243, and the bump 244 extends opposite to the joining portion 241.

The positioning pieces 25 are disposed on the second end 223 corresponding to each hook 23′ of another heat-dissipating fan fixing device 20′ , and the positioning pieces 25 and the hooks 23′ bear against each other. Each positioning piece 25 extends from the side edge of the second end 223, and two side plates 251 are disposed for connecting the positioning piece 25 to the walls of the frame 22. A notch 253 is formed on each positioning piece 25.

The buckle base 26 is disposed on the second end 223 and has through holes 262, 263, for the stopping piece 24′ of another heat-dissipating fan fixing base 20′ to embed therein.

The case 50 has a plurality of punch holes 51, 54 corresponding to each hook 23 and bump 244, for joining with the hook 23 and the bump 244. A fixing block 511 is disposed on the peripheral edge of a side of each punch hole 51, and each fixing block 511 is located on the protruding direction D of each hook 23.

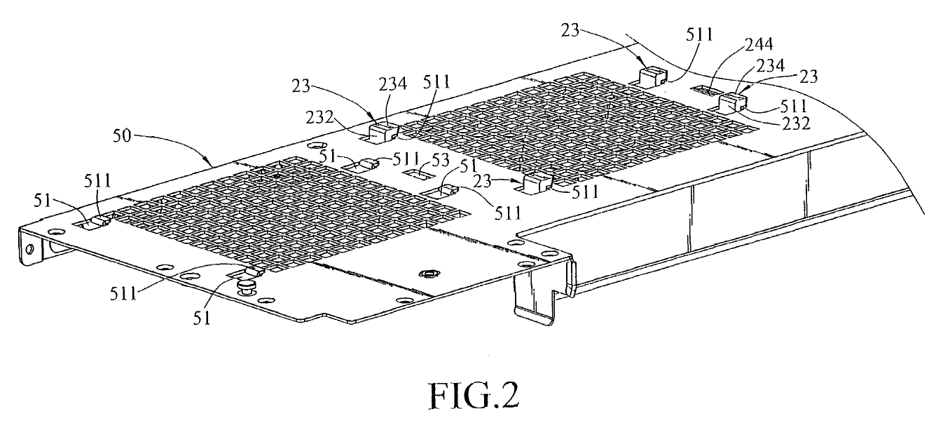

Referring to FIGS. 1A, 1B, and 2, when the heat-dissipating fan fixing device 20 is assembled on the case 50, firstly, the heat-dissipating fan fixing device 20 and the case 50 are positioned relative to each other, and the first end 221 of the frame 22 faces the case 50, so that each hook 23, the bump 244 in the stopping piece 24 of the frame 22 may be inserted into the case 50. Particularly, each hook 23, and the bump 244 in the stopping piece 24 of the frame 22 are inserted into the punch holes 51, 54 of the case 50. After the inserting procedure, the frame 22 is moved along the protruding direction D of each hook 23, until the connecting portion 232 of each hook 23 bears against the edge of each punch hole 51, and the hooking portion 234 of each hook 23 is mutually snapped with the fixing block 511 of each punch hole 51, so as to catch the case 40. The bump 244 of the stopping piece 24 is embedded into the punch hole 54, so as to embed the stopping piece 24 with the case 40. Thus, the frame 22 is stopped by the stopping piece 24 from sliding along the opposite direction of the protruding direction D, thereby being fixed on the case 50. In addition, the isolating piece 228 presses against the case 50 to absorb the vibration of the case 50, thereby achieving the effect of absorbing vibration and reducing noises.

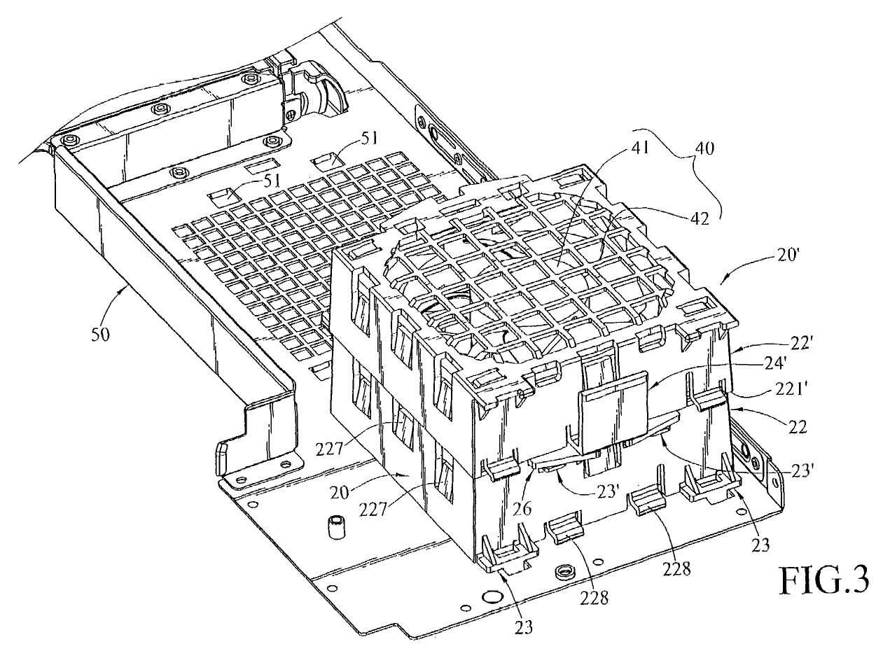

Referring to FIGS. 1A, 1B, and 3, after the heat-dissipating fan fixing device 20 is assembled on the case 50, another heat-dissipating fan fixing device 20′ is stacked on the heat-dissipating fan fixing device 20, so as to enhance the heat dissipation effect. Firstly, another heat-dissipating fan fixing device 20′ and the heat-dissipating fan fixing device 20 are aligned; next, each hook 23′ at a side edge of the first end 221′ of another frame 22′ extends into each positioning piece 25 of the second end 223 of the frame 22; and then, each hook 23′ and the stopping piece 24′ at another side edge of the first end 221′ extend into the buckle base 26 at the second end 223 of the frame 22. Then, another frame 22′ is made to move along the protruding direction D, so that each hook 23′ at one side edge bears against each positioning piece 25 along the protruding direction D. Meanwhile, each hook 23′ and the stopping piece 24′ on another side edge are embedded into the through holes 262, 263 of the buckle base 26. In this manner, the first end 221′ of another frame 22′ is fixed with the second end 223 of the frame 22, and another frame 22′ is stpooed from sliding along the opposite direction of the protruding direction D, such that the heat-dissipating fan fixing devices 20, 20′ are joined with each other. Similarly, if it is intended to continue the stacking process to enhance the heat dissipation performance, it may be achieved through the above steps.

Furthermore, in the first embodiment, when the heat-dissipating fan in the heat-dissipating fan fixing device performs the heat dissipation, the air flow comes into and goes out of the case through the first end and the second end of the frame. However, the normal direction of the first end and the second end of the frame is vertical to the side of the case, thus, the flow in and flow out directions of the air flow is restricted. In order to make the air flow have more flow in and out routes to dissipate the heat, the present invention further discloses a second embodiment.

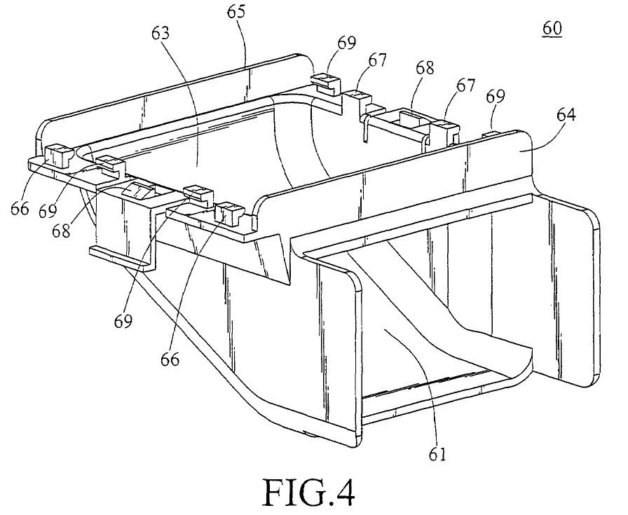

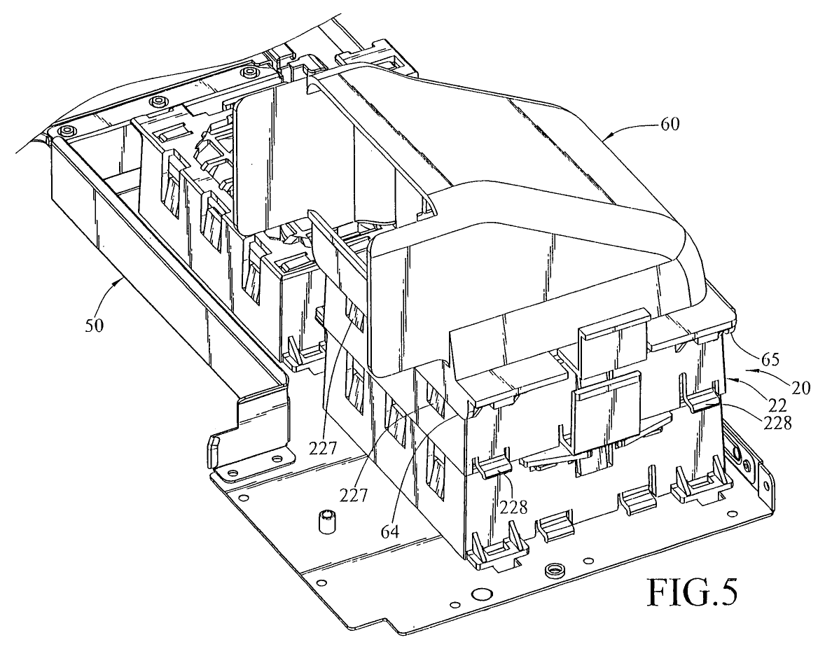

Referring to FIGS. 4 and 5, the heat-dissipating fan fixing base according to the second embodiment of the present invention further includes a wind scooper 60, for joining with the frame 22 of the heat-dissipating fan fixing device 20. A first vent 61 and a second vent 63 are respectively formed at two opposite ends of the wind scooper 60, and a wing piece 64 and a wing piece 65 are respectively extended from each side edge of the second vent 63. In addition, a plurality of first buckle pieces 66 and second buckle pieces 67 are respectively formed on the two side edges of the second vent 63 opposite to the wing pieces 64 and 65 of the the wind scooper 60, and a positioning block 68 is formed on a side edge of the second vent 63 opposite to the wing pieces 64 and 65. Furthermore, the first buckle piece 66 matches with the positioning piece 25, and the second buckle piece 67 and the positioning block 68 match with the buckle base 26, which are mutually buckled each other when the wind scooper 60 is joined with the frame 22 of the heat-dissipating fan fixing device 20. The wind scooper 60 further has a plurality of bearing pieces 69 on the two side edges of the second vent 63 opposite to each wing piece 64, 65.

Referring to FIGS. 4 and 5, when the wind scooper 60 is joined with the frame 22 of the heat-dissipating fan fixing base 20, the second vent 63 faces the second end 223 of the frame 22, and the wing pieces 64 and 65 may be used as the alignment mechanism, such that the first buckle piece 66 is aligned with the positioning piece 25, and the second buckle piece 67 and the positioning block 68 are aligned with the through holes 262, 263 of the buckle base 26. In this manner, the first buckle piece 66 is buckled with the positioning piece 25, and the second buckle piece 67 and the positioning block 68 are buckled with the through holes 262, 263 of the buckle base 26, so as to join the wind scooper 60 with the frame 22 of the heat-dissipating fan fixing device 20. Therefore, the wind scooper 60 transmits the cold air flow to the high heat position to remove the heat energy or absorb the heat, so as to perform the heat-dissipation operation. Furthermore, when the wind scooper is joined with the frame 22, each of the bearing pieces 69 is pressed against the wall of the frame 22, so as to achieve the effect of absorbing vibration and reducing noises.

In the present invention, the snapping mechanism on the heat-dissipating fan fixing device is used to assemble the heat-dissipating fan fixing device on the case or on another heat-dissipating fan fixing device, thus, a plurality of heat-dissipating fan fixing devices may be stacked, so as to form heat-dissipating fans with heat dissipation effect, and to avoid the -malfunction of the computer caused by the failure of a single heat-dissipating fan. Meanwhile, the number of the heat-dissipating fans may be increased or reduced according to the heat-dissipation requirements, and it is easy for the user to remove and change the heat-dissipating fans, so as to avoid the defects of the conventional unity structure that one of the heat-dissipating fan groups cannot be changed or assembled individually. Therefore, the present invention has relative large using variation flexibility. Furthermore, when the heat-dissipating fan fixing bases are assembled on the case or mutually stacked with each other, the staking and assembling process is performed without using any tools, which is convenient for the user to operate.

What is claimed is:

1. A heat-dissipating fan fixing device, for accommodating and fixing a fan, and fixed on a case, comprising:
a frame, having a first end and a second end being opposite to the first end, wherein an accommodating space through the frame is formed between the first end and the second end for accommodating and fixing the fan;
a plurality of hooks, formed on the first end, and extending towards a protruding direction, so as to catch the case; and
a stopping piece, formed on a side edge of the first end, for embedding into the case to stop the frame from sliding along the opposite direction of the protruding direction.

2. The heat-dissipating fan fixing device as claimed in claim 1, further comprising:
a plurality of positioning pieces, disposed on the second end corresponding to each hook of another heat-dissipating fan fixing device, wherein the positioning pieces are provided for bearing against the hooks of another heat-dissipating fan fixing device along the protruding direction, so as to fix the second end of another frame with the first end of the frame; and
a buckle base, disposed on the second end, for the stopping piece of another heat-dissipating fan fixing base to embed therein, so as to limit another heat-dissipating fan fixing base from sliding along the opposite direction of the protruding direction.

3. The heat-dissipating fan fixing device as claimed in claim 1, wherein a plurality of isolating pieces is further disposed at a side edge of the first end of the frame, and presses against the end surface of the case to absorb vibrations when the frame is joined with the case.

4. The heat-dissipating fan fixing device as claimed in claim 1, wherein a plurality of pads is further disposed on the wall between the first end and the second end of the frame, and the pads bear against the fan towards the direction of the accommodating space.

5. The heat-dissipating fan fixing device as claimed in claim 1, wherein the hooks have a connecting portion extending along the side edge of the first end and a hooking portion extending opposite to the connecting portion, and the hooks catch the case via the hooking portions.

6. The heat-dissipating fan fixing device as claimed in claim 1, wherein the stopping piece has a joining portion, a pressing portion, and a bump; the joining portion extends along a side edge of the first end and joins with the pressing portion; and the bump extends opposite to the joining portion.

7. The heat-dissipating fan fixing device as claimed in claim 1, wherein two side plates are disposed for connecting the positioning piece to the wall of the frame, and a notch is formed on the positioning pieces.

8. The heat-dissipating fan fixing device as claimed in claim 1, further comprising a wind scooper, wherein a first vent and a second vent are respectively formed at two opposite ends of the wind scooper; the second vent is used to connect with the second end; and a wing piece is respectively extended from each side edge of the second vent.

9. The heat-dissipating fan fixing device as claimed in claim 8, wherein a plurality of buckle pieces are formed on the two side edges of the second vent opposite to the wing pieces, and a positioning block is formed on a side edge of the second vent opposite to the wing pieces, such that the buckle pieces on one side edge and the positioning block match with the buckle base, and the buckle pieces on the other side edge matches with the positioning piece, which are mutually buckled with each other when the wind scooper is joined with the frame.

10. The heat-dissipating fan fixing device as claimed in claim 8, wherein the wind scooper further has a plurality of bearing pieces on the two side edges of the second vent opposite to each fin, and the bearing pieces are pressed against the wall of the frame when the wind scooper is joined with the frame.
